(19) United States
(12) Patent Application Publication
(10) Pub. No.: US 2013/0175429 A1
(43) Pub. Date: Jul. 11, 2013

(54) IMAGE SENSOR, IMAGE SENSING METHOD, AND IMAGE CAPTURING APPARATUS INCLUDING THE IMAGE SENSOR

(71) Applicants: Pravin Rao, San Jose, CA (US); Ilia Ovsiannikov, Studio City, CA (US)

(72) Inventors: Pravin Rao, San Jose, CA (US); Ilia Ovsiannikov, Studio City, CA (US)

(21) Appl. No.: 13/344,111

(22) Filed: Jan. 5, 2012

(51) Int. Cl. H01L 27/146

(52) U.S. Cl. 250/208.1

(57) ABSTRACT

An image sensor that includes a pixel array including pixels that sample a plurality of modulation signals having different phases from the reflected light and that output pixel output signals corresponding to the plurality of modulation signals, the output pixel output signals being used to generate first images, an integral time adjusting unit that detects a change in an integral time applied to generate the first images such that the integral time adjusting unit compares intensities of the first images to a reference intensity and determines an adjusted integral time when the change in the integral time is detected, and when the change in the integral time is detected, the pixel array generates second images that are subsequent to the first images by applying the adjusted integral time determined by the integral time adjusting unit based on the first images.

### BACKGROUND

1. Field

Embodiments relate to an image sensor, a method of sensing an image, and an image capturing apparatus including the image sensor. Embodiments may also relate to an image sensor capable of, e.g., reducing influence of a change in integral time, a method of sensing an image, and an image capturing apparatus including the image sensor.

2. Description of the Related Art

Technologies relating to image capturing apparatuses and methods of capturing images have advanced at high speed. In order to sense more accurate image information, image sensors have been developed to sense depth information as well as color information of an object.

### SUMMARY

Embodiments may be realized by providing an image sensor that receives reflected light from an object having an output light incident thereon, the image sensor including a pixel array including pixels that sample a plurality of modulation signals having different phases from the reflected light and that output pixel output signals corresponding to the plurality of modulation signals, the output pixel output signals being used to generate first images, an integral time adjusting unit that detects a change in an integral time applied to generate the first images such that the integral time adjusting unit compares intensities of the first images to a reference intensity and determines an adjusted integral time when the change in the integral time is detected, when the change in the integral time is detected, the pixel array generates second images that are subsequent to the first images by applying the adjusted integral time determined by the integral time adjusting unit based on the first images.

The integral time adjusting unit may include an image condition detector that generates a control signal indicating whether the first images are excessively or insufficiently exposed, by comparing the intensities of the first images to the reference intensity, and an integral time calculator that calculates the adjusted integral time in response to the control signal. The image condition detector may compare a maximum image intensity among the intensities of the first images to the reference intensity. The integral time calculator may calculate the adjusted integral time by multiplying a non-adjusted integral time by a ratio of the maximum image intensity and the reference intensity.

The image condition detector may compare a ratio of a maximum image intensity among the intensities of the first images and the reference intensity with a reference value. The ratio of the maximum image intensity and the reference intensity may be equal to or greater than 1. The reference value may be equal to or greater than 0 and may be set as a value equal to or less than an inverse of a factor. The reference intensity may be equal to the factor multiplied by a maximum pixel output signal from among the pixel output signals in a normal state of the image sensor. The integral time calculator may calculate the adjusted integral time by multiplying a non-adjusted integral time by the ratio of the maximum image intensity and the reference intensity.

The image condition detector may compare a ratio of the reference intensity and a smoothed maximum image intensity to a reference value. The smoothed maximum image intensity may be calculated by smooth-filtering a maximum image intensity among the intensities of the first images. The integral time calculator may calculate the adjusted integral time by multiplying a non-adjusted integral time by the ratio of the smoothed maximum image intensity and the reference intensity.

The image sensor may include a depth information calculator that calculates depth information regarding the object by estimating a delay between the output light and the reflected light from the first images that have different phases and that have a same integral time as the second images. Each of the modulation signals may be phase-modulated from the output light by one of about 0°, 90°, 180°, and 270°.

The pixel array may include color pixels that receive wavelengths of the reflected light for detecting color information regarding the object and that generate pixel output signals of the color pixels corresponding to the received wavelengths, and depth pixels that receive wavelengths of the reflected light for detecting depth information regarding the object and that generate pixel output signals of the depth pixels corresponding to the received wavelengths. The image sensor may further include a color information calculator that receives the pixel output signals of the color pixels and calculates the color information. The image sensor may be a time of flight image sensor.

Embodiments may be also be realized by providing an image sensing method using an image sensor that receives reflected light from an object having an output light incident thereon, and the image sensing method includes sampling, from the reflected light, a plurality of modulation signals having different phases, and sequentially generating first images by simultaneously outputting pixel output signals corresponding to the plurality of modulation signals, detecting a change in an integral time applied to generate the first images by comparing intensities of the first images to a reference intensity and determining an adjusted integral time when the change in the integral time is detected, and when the change in the integral time is detected, forming second images that are subsequent to the first images by applying the adjusted integral time to the second images.

Embodiments may also be realized by providing an image sensor for sensing an object that includes a light source driver that emits output light toward the object, a pixel array including a plurality of pixels that convert light reflected from the object into an electric charge to generate first images, an integral time adjusting unit that is connected to the pixel array and that detects a change in an integral time applied to generate the first images such that the integral time adjusting unit compares intensities of the first images to a reference intensity and determines an adjusted integral time when the change in the integral time is detected, and when the change in the integral time is detected, the pixel array generates second images that are subsequent to the first images by applying the adjusted integral time determined by the integral time adjusting unit based on the first images.

When the change in the integral time is detected, the integral time adjusting unit may calculate a maximum image intensity among the intensities of the first images. When the maximum image intensity is less than the reference intensity, the pixel array may generate the second images by applying a non-adjusted integral time. When the maximum image intensity is greater than or equal to the reference intensity, the pixel array may generate the second images by applying the adjusted integral time.

When the change in the integral time is detected, the integral time adjusting unit may calculate a maximum image intensity among the intensities of the first images and calculates a ratio of the maximum image intensity and the reference intensity. When the ratio is less than a reference value, the pixel array may generate the second images by applying a non-adjusted integral time. When the ratio is greater than or equal to the reference value, the pixel array may generate the second images by applying the adjusted integral time.

When the change in the integral time is detected, the integral time adjusting unit may calculate a maximum image intensity among the intensities of the first images, calculates a smoothed maximum image intensity, and calculates a ratio of the smoothed maximum image intensity and the reference intensity. When the ratio is less than a reference value, the pixel array may generate the second images by applying a non-adjusted integral time. When the ratio is greater than or equal to the reference value, the pixel array may generate the second images by applying the adjusted integral time.

The integral time adjusting unit may include an image condition detector that compares the intensities of the first images to the reference intensity and outputs a corresponding signal, and an integral time calculator that receives the corresponding signal from the image condition detector and determines the adjusted integral time.

### BRIEF DESCRIPTION OF THE DRAWINGS

Features will become apparent to those of ordinary skill in the art by describing in detail exemplary embodiments with reference to the attached drawings in which:

FIG. 1 illustrates a block diagram of an image sensor, according to an exemplary embodiment;

FIGS. 2A and 2B illustrate diagrams for describing exemplary operations of the image sensor illustrated in FIG. 1;

FIGS. 3A and 3B illustrate diagrams for showing exemplary alignments of pixels illustrated in FIG. 1;

FIG. 4 illustrates graphs of exemplary modulation signals used when the image sensor illustrated in FIG. 1 senses an image;

FIG. 5 illustrates a diagram showing an exemplary sequence of images captured from continuously received reflected light;

FIG. 6 illustrates a diagram showing an exemplary sequence of images when an integral time is reduced;

FIG. 7 illustrates a diagram showing an exemplary sequence of images when an integral time is increased;

FIG. 8 illustrates a flowchart of an image sensing method, according to an exemplary embodiment;

FIG. 9 illustrates a flowchart of an image sensing method, according to another exemplary embodiment;

FIG. 10 illustrates a flowchart of an image sensing method, according to another exemplary embodiment;

FIG. 11 illustrates a block diagram of an image capturing apparatus, according to an exemplary embodiment;

FIG. 12 illustrates a block diagram of an image capturing and visualization system, according to an exemplary embodiment; and

FIG. 13 illustrates a block diagram of a computing system, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

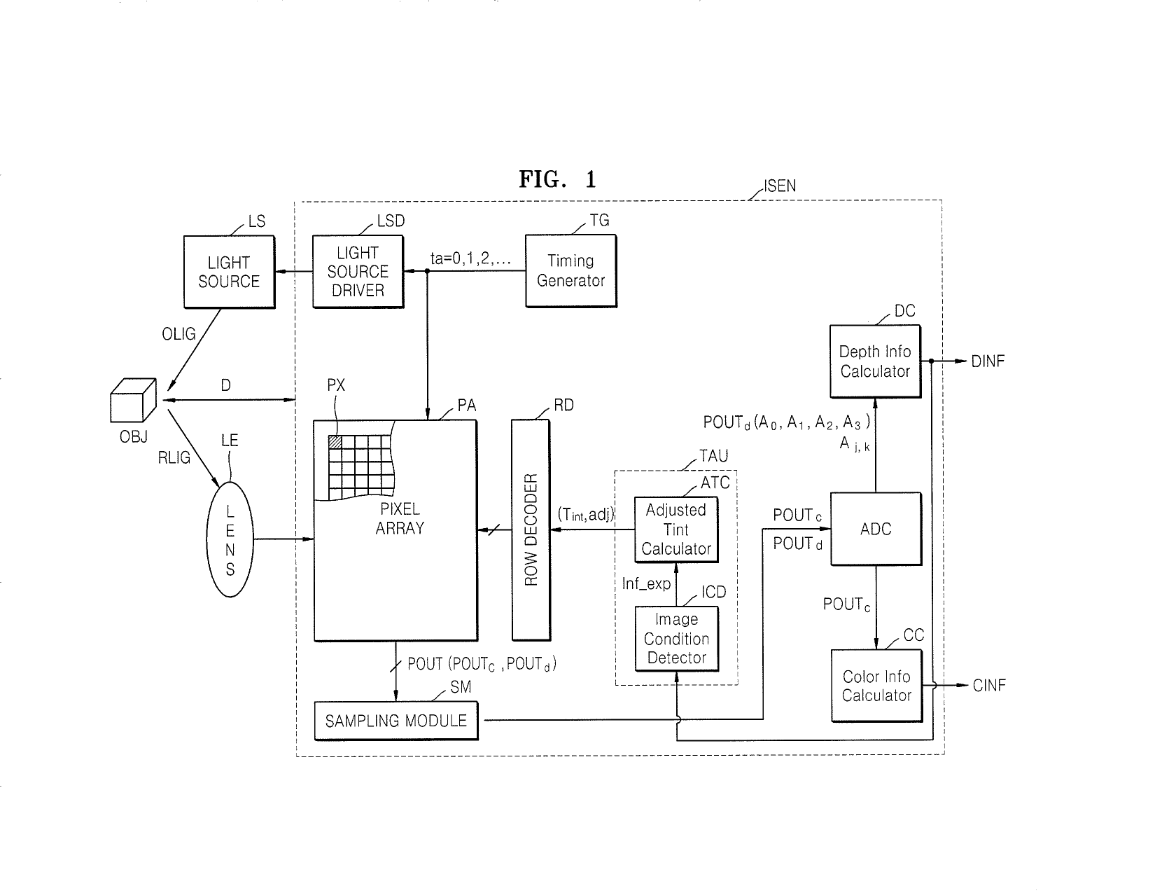

FIG. 1 illustrates a block diagram of an image sensor ISEN according to an exemplary embodiment.

Referring to FIG. 1, the image sensor ISEN includes a pixel array PA, a timing generator TG, a row driver RD, a sampling module SM, an analog-digital converter ADC, a color information calculator CC, a depth information calculator DC, and an integral time adjusting unit TAU. The image sensor ISEN may be a time-of-flight (TOF) image sensor that senses image information (color information C_{INF} and depth information D_{INF}) of an object OBJ.

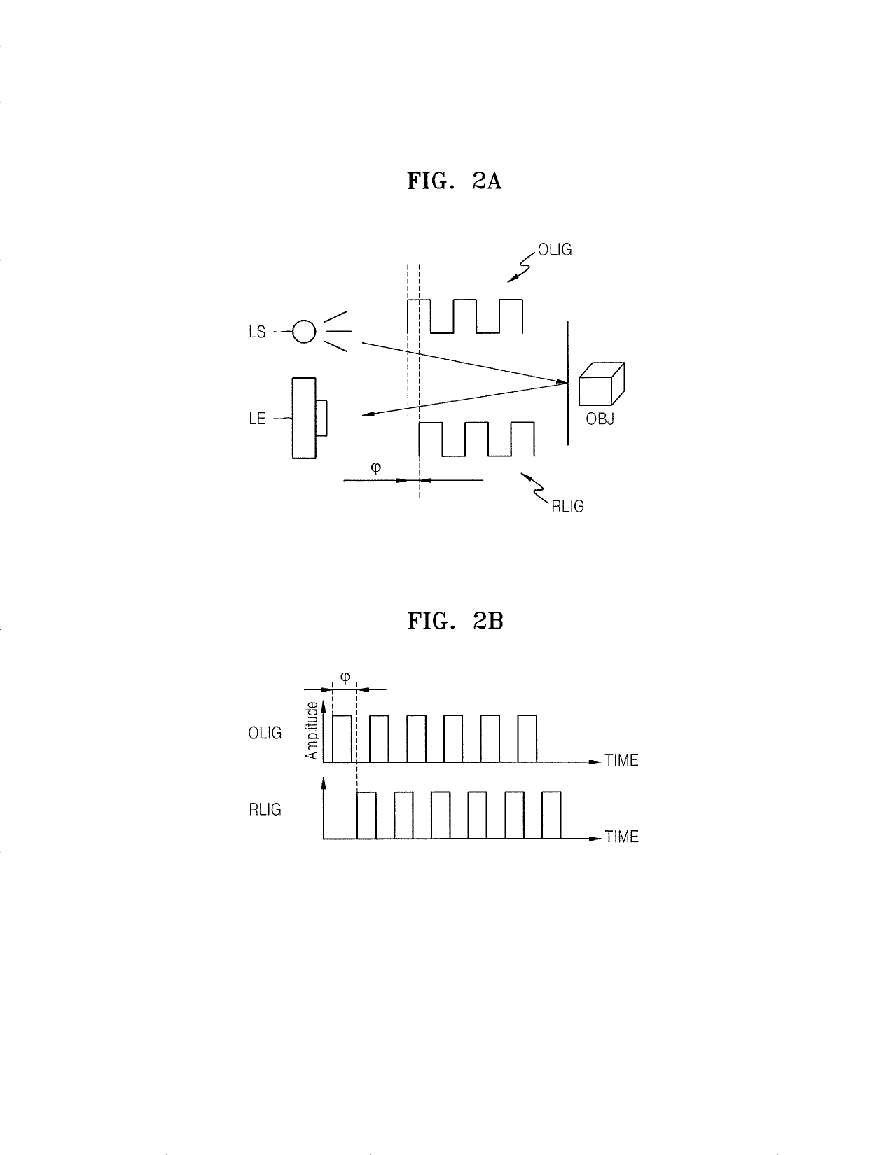

As shown in FIG. 2A, the image sensor ISEN may sense depth information D_{INF} of the object OBJ from reflected light RLIG received through a lens LE after output light OLIG emitted from a light source LS has been incident thereon. In this case, as shown in FIG. 2B, the output light OLIG and the reflected light RLIG may have periodical waveforms shifted by a phase delay of φ relative to one another. The image sensor ISEN may sense color information C_{INF} from the visible light of the object OBJ.

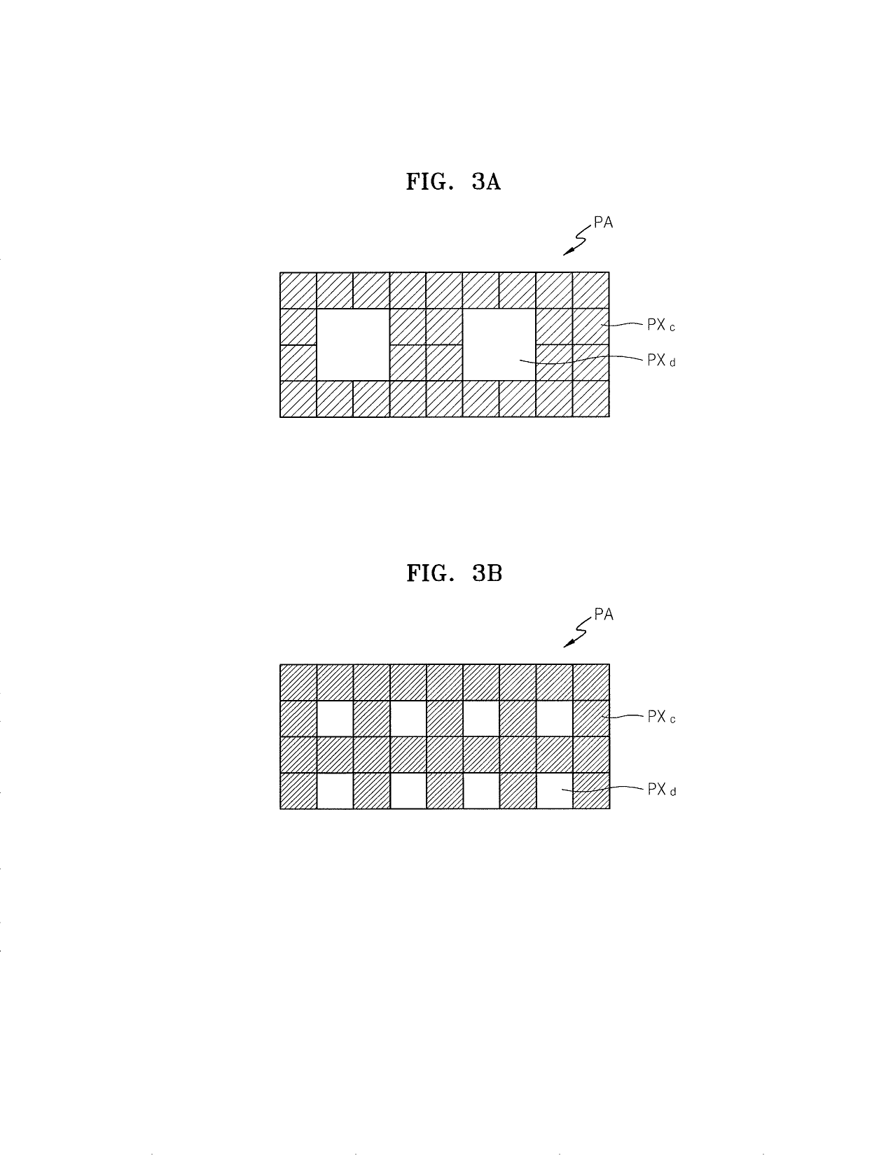

The pixel array PA of FIG. 1 may include a plurality of pixels PX arranged at intersections between rows and columns. However, embodiments are not limited thereto, e.g., the pixel array PA may include the pixels PX arranged in various ways. For example, FIGS. 3A and 3B illustrate exemplary diagrams of the pixels PX of the pixel array PA of the image sensor ISEN of FIG. 1. As shown in FIG. 3A, depth pixels PXd may be larger in size than color pixels PXc, and the depth pixels PXd may be smaller in number than the color pixels PXc. As shown in FIG. 3B, the depth pixels PXd and the color pixels PXc may be the same size, and the depth pixels PXd may be smaller in number than the color pixels PXc. Further, in a particular configuration, the depth pixels PXd and the color pixels PXc may be alternately arranged in alternate rows, e.g., a row may contain all color pixels PXc followed by a row containing alternating color pixels PXc and depth pixels PXd. The depth pixels PXd may sense infrared light of the reflected light RUG. The color pixel array PA may also include depth pixels only if the sensor is capable of capturing only range images without color information.

Although the color pixels PXc and the depth pixels PXd are separately arranged in FIGS. 3A and 3B, embodiments are not limited thereto. For example, the color pixels PXc and the depth pixels PXd may be integrally arranged.

The depth pixels PXd may each include a photoelectric conversion element (not shown) for converting the reflected light RLIG into an electric change. The photoelectric conversion element may be, e.g., a photodiode, a phototransistor, a photo-gate, a pinned photodiode, and so forth. Also, the depth pixels PXd may each include transistors connected to the photoelectric conversion element. The transistors may control the photoelectric conversion element or output an electric change of the photoelectric conversion element as pixel signals. For example, read-out transistor included in each of the depth pixels PXd may output an output voltage corresponding to reflected light received by the photoelectric conversion element of each of the depth pixels PXd as pixel signals. Also, the color pixels PXc may each include a photoelectric conversion element (not shown) for converting the visible light into an electric change. A structure and a function of each pixel will not be explained in detail for clarity.

If the pixel array PA of the present embodiment separately includes the color pixels PXc and the depth pixels PXd, e.g., as shown in FIGS. 3A and 3B, pixel signals may be divided into color pixel signals POUTc and depth pixel signals POUTd. The color pixel signals POUTc are output from the color pixels PXc and may be used to obtain color information C_{INF}. The depth pixel signals POUTd are output from the depth pixels PXd and may be used to obtain depth information D_{INF}.

Referring to FIG. 1, the light source LS may be controlled by a light source driver LSD that may be located inside or outside the image sensor ISEN. The light source LS may emit the output light OLIG modulated at a time (clock) ‘ta’ applied by the timing generator TG. The timing generator TG may also control other components of the image sensor ISEN, e.g., the row decoder RD and the sampling module SM, etc.

The timing generator TG may control the depth pixels PXd to be activated, e.g., so that the depth pixels PXd of the image sensor ISEN may demodulate from the reflected light RLIG synchronously with the clock ‘ta’. The photoelectric conversion element of each the depth pixels PXd may output electric charges accumulated with respect to the reflected light RLIG for a depth integration time Tᵢₙₜ_{_{—}}Dep as depth pixel signals POUTd. The photoelectric conversion element of each the color pixels PXc may output electric charges accumulated with respect to the visible light for a color integration time Tᵢₙₜ_{_{—}}Col as color pixel signals POUTc. A detailed explanation of the color integration time Tᵢₙₜ_{_{—}}Col and the depth integration time Tᵢₙₜ_{_{—}}Dep will be made with reference to the integral time adjusting unit TAU.

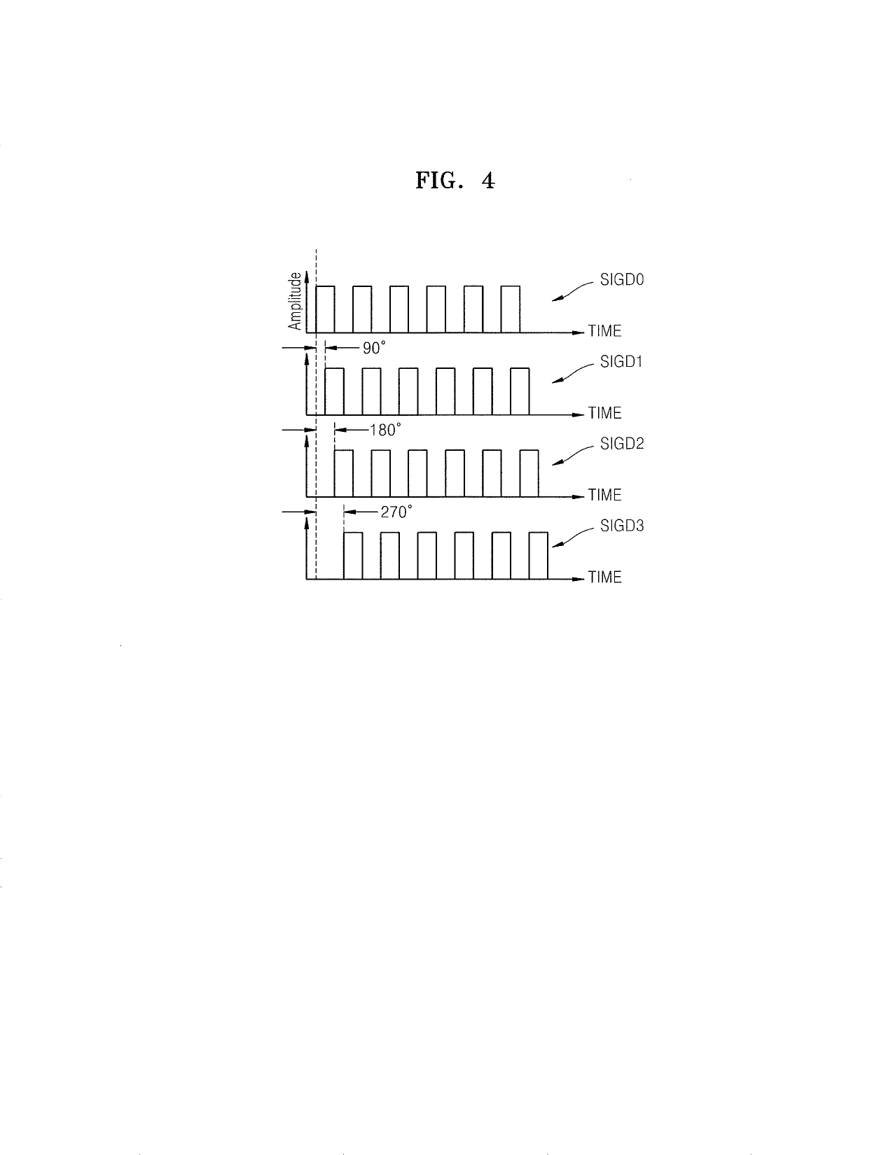

The depth pixel signals POUTd of the image sensor ISEN may be output to correspond to a plurality of demodulated optical wave pulses from the reflected light RLIG that includes modulated optical wave pulses. For example, FIG. 4 illustrates a diagram of exemplary modulated signals used to illuminate an image in the image sensor ISEN of FIG. 1. Referring to FIG. 4, each of the depth pixels PXd may receive a demodulation signal, e.g., SIGD0, and illumination by four modulated signals SIGD0 through SIGD3 whose phases may be shifted respectively by about 0, 90, 180, and 270 degrees from the output light OLIG, and output corresponding depth pixel signals POUTd. The resulting depth pixel outputs for each captured frame are designated correspondingly as A0, A1, A2 and A3. Also, the color pixels PXc receive illumination by the visible light and output corresponding color pixel signals POUTc. According to another exemplary embodiment, referring to FIG. 4, each of the depth pixels PXd may receive illumination by one modulated signal only, e.g., SIGD0, while the demodulation signal phase changes from SIGD0 to SIGD3 to SIGD2 to SIGD1. The resulting depth pixel outputs for each captured frame are also designated correspondingly as A0, A1, A2 and A3.

Referring back to FIG. 1, the sampling module SM may sample depth pixel signals POUTd from the depth pixels PXd and send the depth pixel signals POUTd to the analog-to-digital converter ADC. The sampling module may be a part of the pixel array. Also, the sampling module SM may sample such color pixel signals POUTc from the color pixels PXc and send the color pixel signals POUTc to the analog-to-digital converter ADC. The analog-to-digital converter ADC may convert the pixel signals POUTc and POUTd each having an analog voltage value into digital data. Even though the sampling module SM or the analog-to-digital converter ADC may operate at the different times for the color pixel signals POUTc and the depth pixel signals POUTd, the image sensor may output the color information C_{INF} in synchronization with the depth information D_{INF}. For example, the sampling module SM may read out the pixel signals POUTc and POUTd simultaneously.

The color information calculator CC may calculate the color information C_{INF} from the color pixel signals POUTc converted to digital data by the analog-to-digital converter ADC.

The depth information calculator DC may calculate the depth information D_{INF} from the depth pixel signals POUTd=A0 through A3 converted to digital data by the analog-to-digital converter ADC. For example, the depth information calculator DC estimates a phase delay φ between the output light OLIG and the reflected light RUG as shown in Equation 1, and determines a distance D between the image sensor ISEN and the object OBJ as shown in Equation 2.

$$\begin{matrix}ϕ = arctan ( \frac{{A}_{3} - {A}_{1}}{{A}_{2} - {A}_{0}} ) & [ Equation 1 ] \\ D = \frac{c}{4 \cdot {F}_{m} \cdot π} * ϕ & [ Equation 2 ]\end{matrix}$$

In Equation 2, the distance D between the image sensor ISEN and the object OBJ is a value measured in the unit of meter, Fm is a modulation wave period measured in the unit of second, and ‘c’ is a speed of light measured in the unit of m/s. Thus, the distance D between the image sensor ISEN and the object OBJ may be sensed as the depth information D_{INF} from the depth pixel signals POUTd output from the depth pixels PXd of FIG. 3 with respect to the reflected light RUG of the object OBJ. As shown in Equations 1 and 2, in order to form (calculate) one scene regarding the object OBJ, first through fourth pixel output signals A0 through A3 corresponding to the first through fourth modulation signals SIGD0 through SIGD3 respectively modulated by about 0°, 90°, 180°, and 270° may be used and/or may be required.

A method of calculating the depth information D_{INF} in units of the pixels PX is described above. A method of calculating the depth information D_{INF} in units of images each formed of the pixel output signals POUT from N*M pixels PX (N and M are integers equal to or greater than 2) will now be described.

FIG. 1 does not illustrate an image formed of the pixel output signals POUT output from a plurality of pixels PX. However, a sampling unit SM connected to an output terminal of the pixel array PA or a buffer (not shown) before or after the analog-digital converter ADC may form the pixel output signals POUT output from the plurality of pixels PX as a single image.

Further, the pixel output signals POUT may be sensed by excessively or insufficiently exposed pixels PX. The pixel output signals POUT (image values) output from the excessively or insufficiently exposed pixels PX may be inaccurate. The image sensor ISEN may reduce the possibility of and/or prevent the above-described error by automatically detecting an integral time applied to the excessively or insufficiently exposed pixels PX (an image) and adjusting the integral time to a new integral time. A detailed description of the integral time will now be provided.

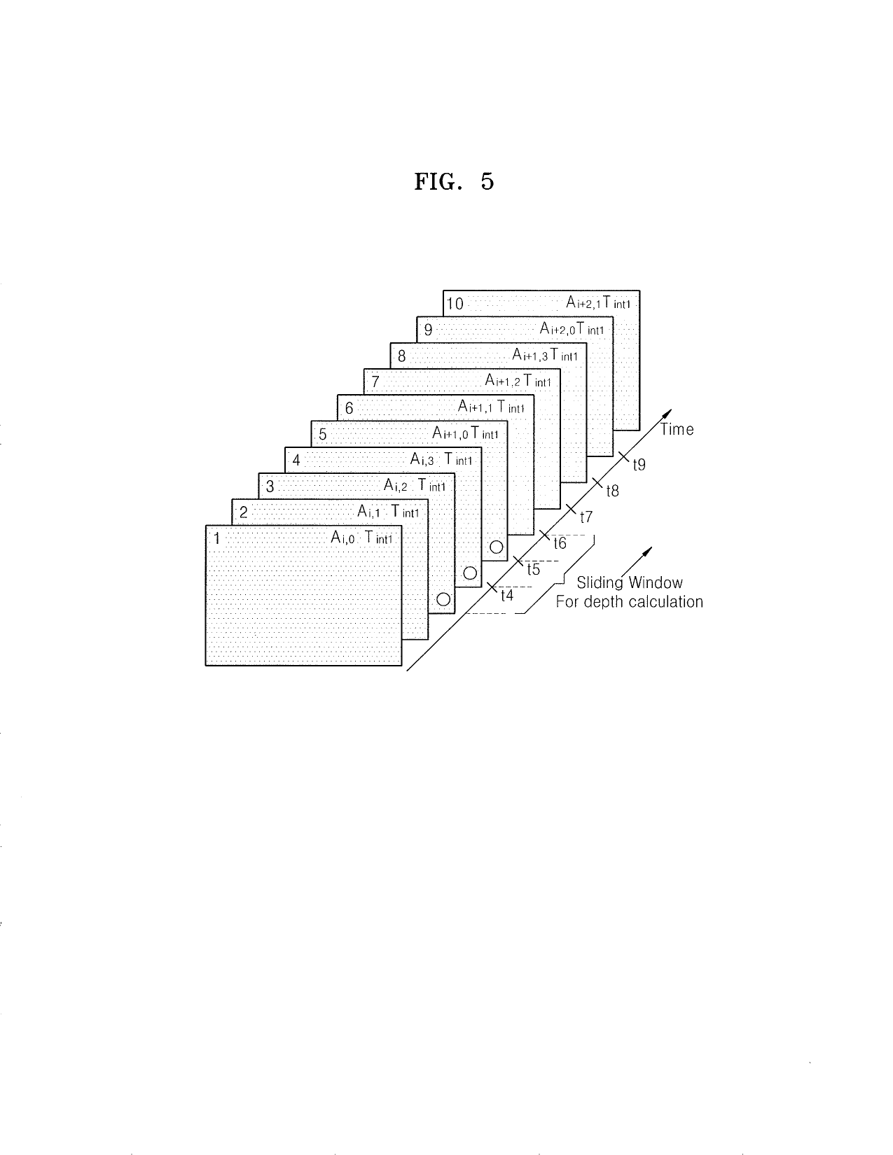

Referring to FIG. 5, according to an exemplary embodiment, the images have the same integral time Tᵢₙₜ (a first integral time Tᵢₙₜ₁). A method of calculating the depth information D_{INF} (the distance D) in this case will now be described.

In FIG. 5, four images substituted in Equations 3 through 8, below, to calculate the depth information D_{INF} at one time are included in a sliding window. If the image sensor ISEN completely calculates the depth information D_{INF} regarding the images A_{i,0} through A_{i,3} of the i^{th} scene, the sliding window moves in a direction of an arrow, as illustrated in FIG. 5. As such, it is assumed that the image sensor ISEN captures an image A_{i+1,0} that is newly included in the sliding window currently at a time t5 after the image A_{i,3}. Also, it is assumed that the three images A_{i,1} through A_{1,3} recently captured by the image sensor ISEN and the image A_{1+1,0} currently captured at the time t5 by the image sensor ISEN have the same integral time Tᵢₙₜ (the first integral time Tᵢₙₜ₁).

In this case, like a method of calculating the depth information D_{INF} regarding the first through fourth pixel output signals A0 through A3 by using Equations 1 and 2, the depth information D_{INF} (the distance D) at the time t5 may be calculated by calculating a phase delay φ₀ at the time t5 that is obtained according to Equation 3 below, and substituting the phase delay φ₀ in Equation 4.

$$\begin{matrix}{ϕ}_{0} = arctan ( \frac{{A}_{i , 3} - {A}_{i , 1}}{{A}_{i , 2} - {A}_{i + 1 , 0}} ) & [ Equation 3 ] \\ D = \frac{c}{4 \cdot {F}_{m} \cdot π} * {ϕ}_{0} & [ Equation 4 ]\end{matrix}$$

In this manner, phase delays φ₁, φ₂, φ₃, and φ₄ may be calculated by substituting values of four images newly captured at subsequent times (an image A_{i+1,1} at a time t6, an image A_{i+1,2} at a time t7, an image A_{i+1,3} at a time t8, and an image A_{i+2,0} at a time t9) according to Equations 5 through 8, respectively. The phase delays φ₁, φ₂, φ₃, and φ₄ may be used to calculate the depth information D_{INF} (the distance D) as shown in Equation 4.

$$\begin{matrix}{ϕ}_{1} = arctan ( \frac{{A}_{i , 3} - {A}_{i + 1 , 1}}{{A}_{i , 2} - {A}_{i + 1 , 0}} ) & [ Equation 5 ] \\ {ϕ}_{2} = arctan ( \frac{{A}_{i , 3} - {A}_{i + 1 , 1}}{{A}_{i + 1 , 2} - {A}_{i + 1 , 0}} ) & [ Equation 6 ] \\ {ϕ}_{3} = arctan ( \frac{{A}_{i + 1 , 3} - {A}_{i + 1 , 1}}{{A}_{i + 1 , 2} - {A}_{i + 1 , 0}} ) & [ Equation 7 ] \\ {ϕ}_{4} = arctan ( \frac{{A}_{i + 1 , 3} - {A}_{i + 1 , 1}}{{A}_{i + 1 , 2} - {A}_{i + 2 , 0}} ) & [ Equation 8 ]\end{matrix}$$

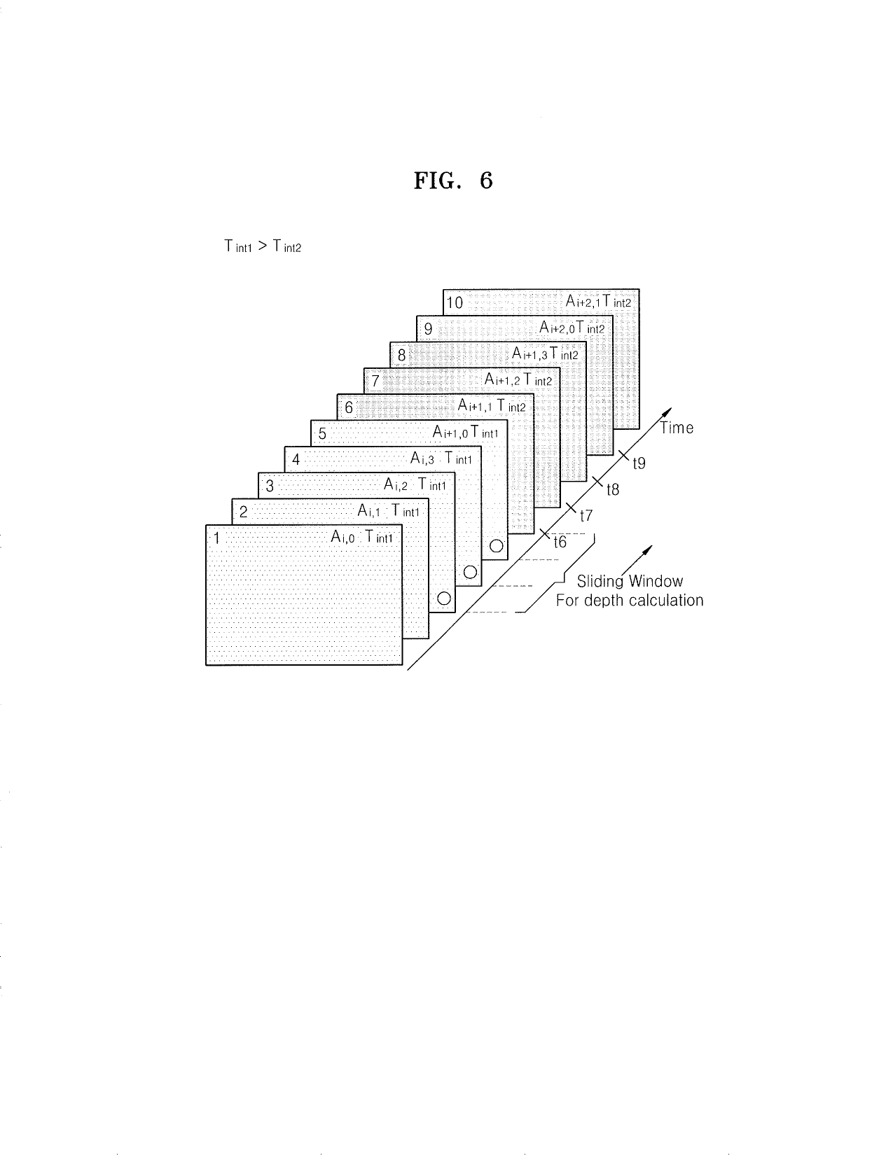

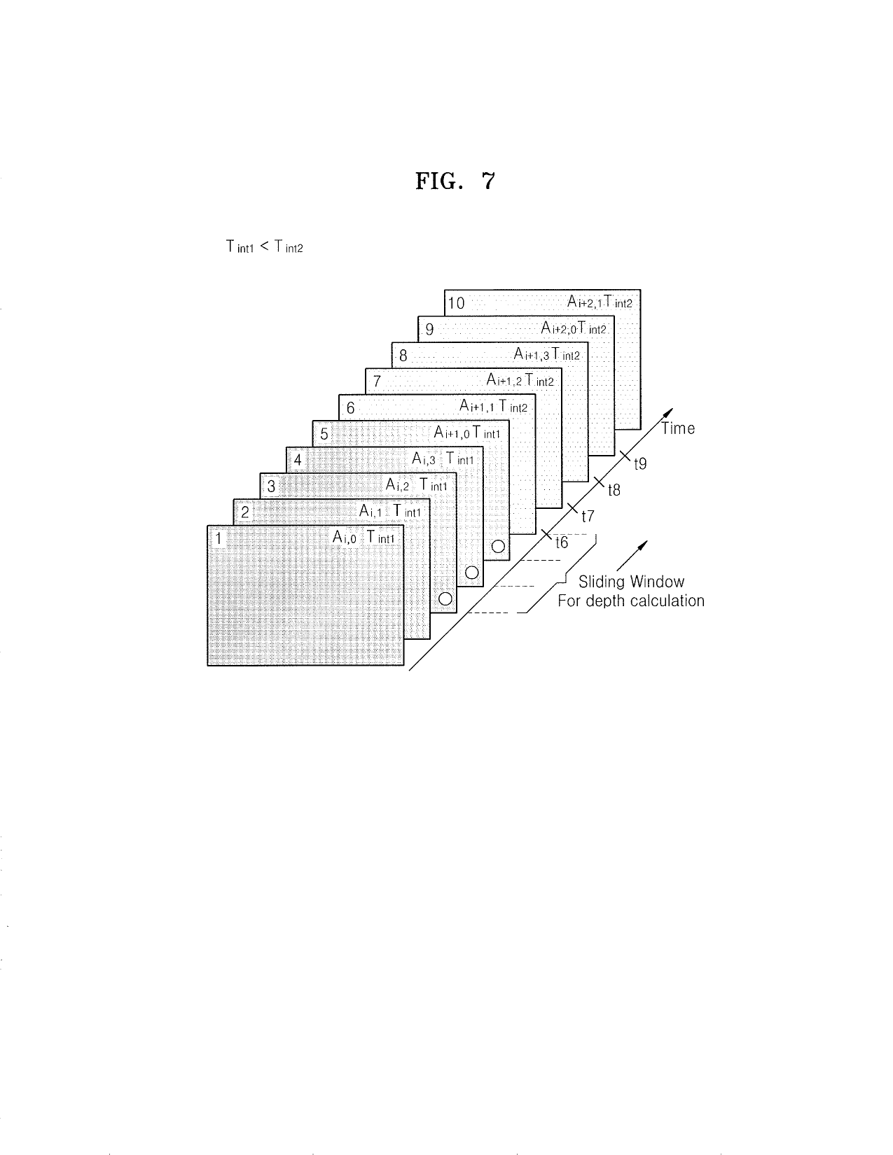

Referring to FIGS. 6 and 7, according to another exemplary embodiment, the integral time Tᵢₙₜ of the three recently captured images A_{i,2}, A_{i,3}, and A_{i+1,0} (the first integral time Tᵢₙₜ₁) may differ from the integral time Tᵢₙₜ of the image A_{i+1,1} newly captured at the time t6 (a second integral time Tᵢₙₜ₂). For example, as discussed above, the image sensor ISEN may have automatically detected an integral time and adjusted the integral time to a new integral time based on excessively or insufficiently exposed pixels PX. As such, the integral time may change from a non-adjusted integral time to an adjusted integral time. That is, as illustrated in FIGS. 6 and 7, the integral time Tᵢₙₜ may be increased or decreased, e.g., while the depth information D_{INF} is calculated.

If a plurality of (four) images of different phases are substituted into Equations 3 through 8 to calculate the depth information D_{INF} have different integral times Tᵢₙₜ, the depth information calculator DC may stop the calculation of the depth information D_{INF} until the images have the same integral time Tᵢₙₜ. For example, if the integral time Tᵢₙₜ has changed from the first integral time Tᵢₙₜ₁ to the second integral time Tᵢₙₜ₂ at the time t6, as illustrated in FIGS. 6 and 7, the depth information calculator DC may stop the calculation of the depth information D_{INF} until all images substituted in Equation 8 at the time t9 have the same integral time Tᵢₙₜ (the second integral time Tᵢₙₜ₂). However, if the calculation of the depth information D_{INF} is stopped when the integral time Tᵢₙₜ has changed, an operation speed of the image sensor ISEN is reduced.

Further, if the integral time Tᵢₙₜ has changed, an image to which the changed integral time Tᵢₙₜ is applied may be excessively or insufficiently exposed. If an image is excessively or insufficiently exposed, values of images substituted in Equations 3 through 8 are not constants, the depth information D_{INF} may be calculated inaccurately or may not be calculated.

In this case, the image sensor ISEN may automatically detect the changed integral time Tᵢₙₜ, may adjust the detected integral time Tᵢₙₜ, and may accurately calculate the depth information D_{INF} without stopping the calculation of the depth information D_{INF}. A detailed description thereof will now be provided.

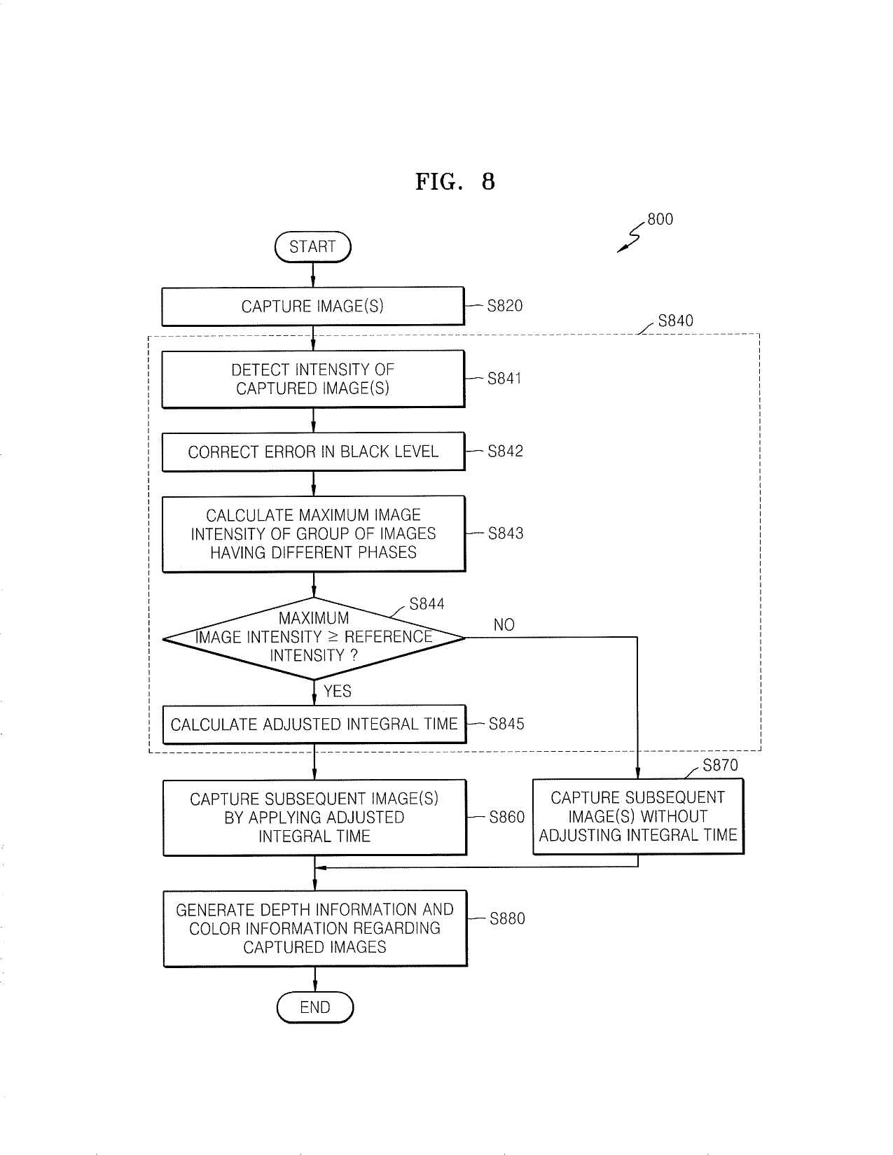

FIG. 8 illustrates a flowchart of an image sensing method 800, according to an exemplary embodiment.

Referring to FIGS. 1 and 8, in the image sensing method 800, an image(s) A_{j,k} is captured as described above in relation to FIGS. 1 through 7 (operation S820). The integral time adjusting unit TAU of the image sensor ISEN may automatically detect whether the integral time Tᵢₙₜ has changed in the image A_{j,k}, and adjust the changed integral time Tᵢₙₜ (operation S840). For this, the integral time adjusting unit TAU of the image sensor ISEN may include, e.g., an image condition detector ICD and an integral time calculator ATC (adjusted Tᵢₙₜ calculator in FIG. 1).

The image condition detector ICD compares an intensity I of the image A_{j,k} to a reference intensity I_{ref} and determines whether the image A_{j,k} is excessively or insufficiently exposed. For example, the image condition detector ICD detects the intensity I of the image A_{j,k} by using Equation 9 (operation S841).

$$I ( j , k ) = \frac{1}{MN} {\sum }_{x = 1}^{M} {\sum }_{y = 1}^{N} {A}_{j , k} ( x , y ) \qquad [ Equation 9 ]$$

As shown in Equation 9, the intensity I of the image A_{j,k} is an average value of the pixel output signals POUT output from N*M pixels PX for forming the image A_{j,k}. In Equation 9, (x,y) represents a coordinate in the image A_{j,k} (a coordinate of each pixel PX). It is assumed that the image A_{j,k}, of which the intensity I is currently calculated, has the same integral time Tᵢₙₜ as a previously captured image A_{j,k-1} or A_{j-1,k}.

Equation 9 shows a case when the image A_{j,k} has a value of zero (“0”) in a black level. However, the image A_{j,k} may have an arbitrary value B that is not zero (“0”) with respect to the reflected light RLIG in the black level. That is, if the image A_{j,k} has the arbitrary value B in the black level, the arbitrary value B has to be subtracted from a value of each pixel PX (each pixel output signal POUT) of the image A_{j,k} (error correction) before calculating the intensity I of the image A_{j,k}, as represented in Equation 10 (operation S842).

$$I ( j , k ) = \frac{1}{MN} {\sum }_{x = 1}^{M} {\sum }_{y = 1}^{N} ( {A}_{j , k} ( x , y ) - B ) \qquad [ Equation 10 ]$$

Hereinafter, for accuracy of calculation, it is assumed that the intensity I of the image A_{j,k} is calculated by using Equation 10.

The image condition detector ICD may calculate the intensities I of a plurality of (four) images having different phases by using the Equation 10, and may select a maximum image intensity IM from among the intensities I. For example, the image condition detector ICD may calculate the maximum image intensity IM of images A_{j,0}, A_{j,1}, A_{j,2}, and A_{j,3} having phases of about 0°, 90°, 180°, and 270°, respectively, by using Equation 11 (operation S843).

I_{M}(j)=max(I(j,0),I(j,1),I(j,2),I(j,3)) [Equation 11]

Then, the image condition detector ICD may compare the maximum image intensity I_{M} to the reference intensity I_{ref} as represented in Inequation 12 (operation S844), and detect whether the image A_{j,k} is excessively or insufficiently exposed by the corresponding pixel.

I_{M}≧I_{ref} [Inequation 12]

In this case, the reference intensity I_{ref} is a value obtained by multiplying a maximum pixel output signal p_{M} by a factor α as represented in Equation 13, and corresponds to a certain ratio of the maximum pixel output signal p_{M}.

I_{ref}=α·p_{M}, where 0<α<1 [Equation 13]

In Equation 13, the maximum pixel output signal p_{M} is a maximum value of pixel output signals P_{OUT} for forming a general image that is captured by a general image capturing apparatus and is not excessively or insufficiently exposed, and the factor α is a value between 0 and 1. For example, the maximum pixel output signal is one from one the pixel output signals in a normal state of the image sensor.

In the above description, the maximum image intensity I_{M}, which is the largest value from among the intensities I of the plurality of (four) images having different phases, is compared to the reference intensity I_{ref} to detect whether the image A_{j,k} is excessively or insufficiently exposed because if a smaller intensity I having a value less than the maximum image intensity I_{M} is compared to the reference intensity I_{ref}, an image having an intensity I greater than the smaller intensity I cannot be detected.

If the factor α in Equation 13 is set as a large value, a larger number of images are detected as being excessively or insufficiently exposed and thus the image condition detector ICD may more accurately detect the excessively or insufficiently exposed images. If the factor α is set as a small value, the integral time calculator ATC adjusts the integral time Tᵢₙₜ less frequently and thus an operation speed of the image sensor ISEN may be increased.

Back in Inequation 12, if Inequation 12 is true (“YES” in operation S844), the image condition detector ICD determines that the image A_{j,k} is excessively or insufficiently exposed. Accordingly, the image condition detector ICD may transmit to the integral time calculator ATC information Inf_exp about the changed integral time Tᵢₙₜ.

Continuously referring to FIGS. 1 and 8, the integral time calculator ATC receives a control signal, calculates an adjusted integral time T_{int,adj} by multiplying the integral time Tᵢₙₜ of the image A_{j,k} by a ratio of the maximum image intensity I_{M} and the reference intensity I_{ref} as represented in Equation 14, and applies the adjusted integral time T_{int,adj} to the pixel array PA (operation S845).

T_{int,adj}(j,k)=Tᵢₙₜ(j,k)*(I_{ref}/I_{M}(j)) [Equation 14]

As such, the integral time calculator ATC may reduce an influence of the changed integral time Tᵢₙₜ by adjusting the changed integral time Tᵢₙₜ according to the ratio of the maximum image intensity IM and the reference intensity I_{ref}. Thereafter, the pixel array PA may capture a subsequent image(s) by applying the adjusted integral time T_{int,adj} (operation S860).

If Inequation 12 is false (“NO” in operation S844), the pixel array PA may capture the subsequent image without adjusting the integral time Lᵢₙₜ (i.e., while maintaining the integral time Tᵢₙₜ) (operation S870). That is, the pixel array PA uses the adjusted integral time T_{int,adj} instead of the integral time Tᵢₙₜ only if the adjusted integral time T_{int,adj} is applied.

The depth information calculator DC generates the depth information D_{INF} regarding the captured images (operation S880).

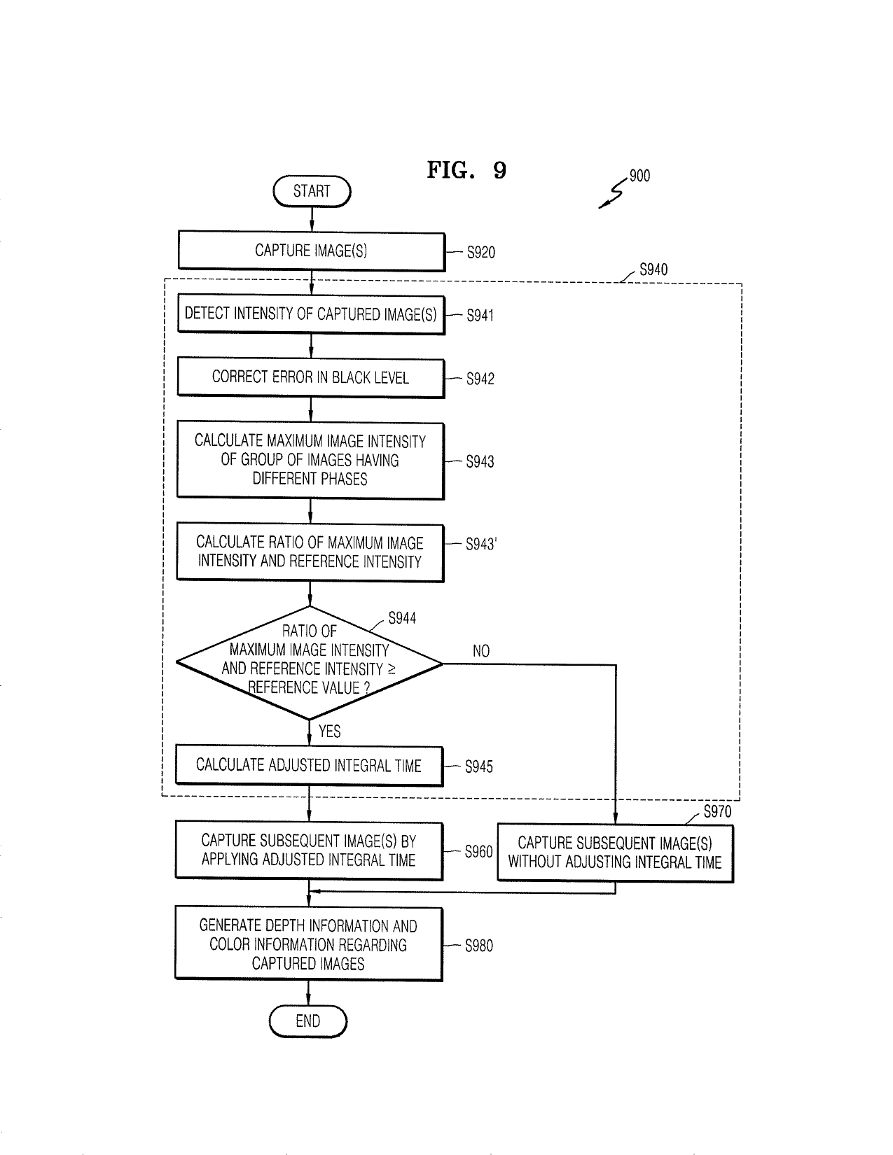

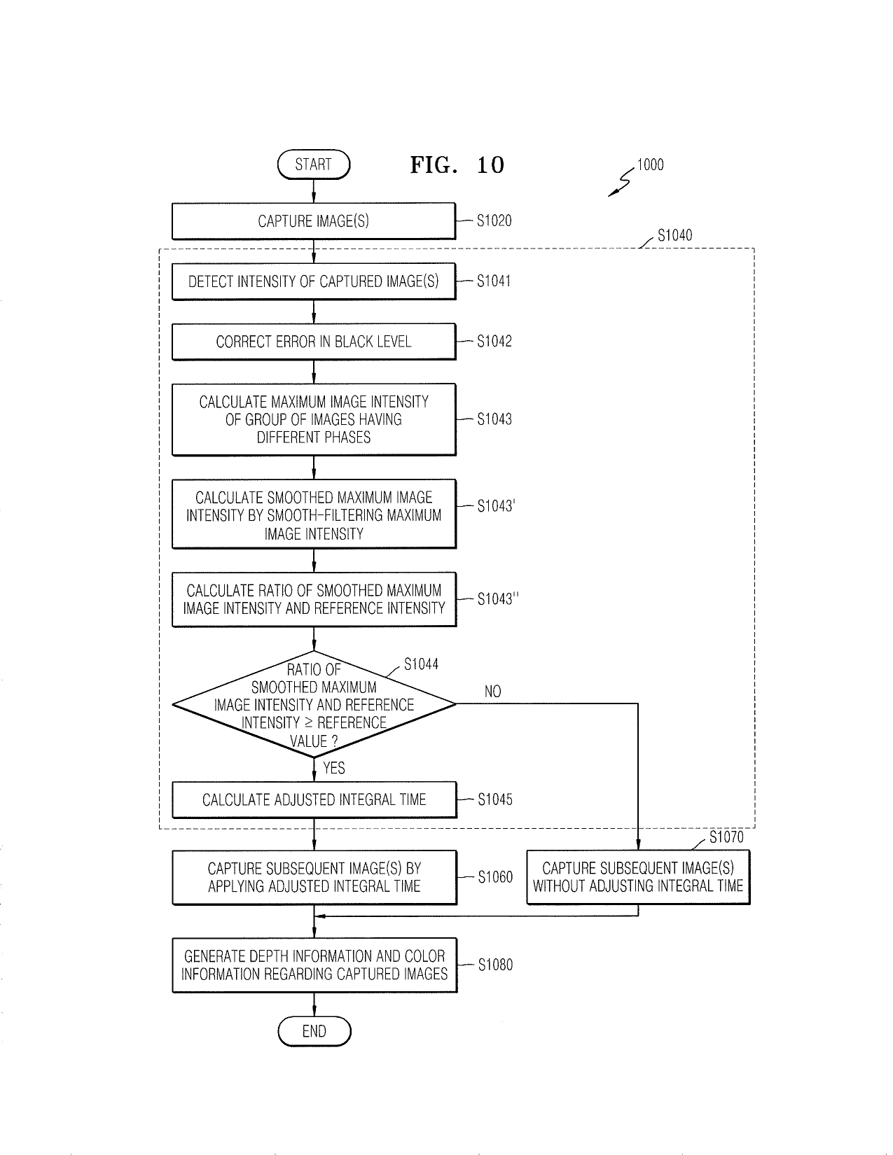

The integral time adjusting unit TAU, e.g., according to the image sensing method 800 illustrated in FIG. 8, may detect whether the integral time Tᵢₙₜ is changed by comparing the maximum image intensity I_{M} calculated according to Equation 11 to the reference intensity I_{ref}. However, embodiments of methods of detecting whether the integral time Tᵢₙₜ is changed are not limited thereto. For example, alternative examples thereof will now be described with reference to FIGS. 9 and 10.

FIG. 9 illustrates a flowchart of an image sensing method 900, according to another exemplary embodiment.

Referring to FIG. 9, operations 5920, S941, S942, and S943 of the image sensing method 900 are substantially the same as operations S820, S841, S842, and S843, respectively, of the image sensing method 800 illustrated in FIG. 8. However, the integral time adjusting unit TAU according to the image sensing method 900 may calculate a ratio R between the maximum image intensity I_{M} and the reference intensity I_{ref} (operation S943′). The integral time adjusting unit TAU may compare the ratio R to a reference value T_{R} as represented in Inequation 15 (operation S944), thereby detecting whether the integral time Tᵢₙₜ is changed.

R(j)≧T_{R} [Inequation 15]

In Inequation 15, the ratio R between the maximum image intensity I_{M} and the reference intensity I_{ref} may be calculated according to Equation 16 and may have a value greater than 1.

$$R ( j ) = max ( \frac{{I}_{M} ( j )}{{I}_{ref}} , \frac{{I}_{ref}}{{I}_{M} ( j )} ) \qquad [ Equation 16 ]$$

The reference value T_{R} in Inequation 15 may be equal to or greater than 0 and may be less than an inverse of the factor α that is multiplied by the maximum pixel output signal p_{M} in Equation 13 above to calculate the reference intensity I_{ref}, as represented in Inequation 17.

$$0 \leq {T}_{R} < \frac{1}{α} \qquad [ Inequation 17 ]$$

If Inequation 15 is true (“YES” in operation S944), the image condition detector ICD determines that the image A_{j,k} is excessively or insufficiently exposed, i.e., that the integral time Tᵢₙₜ has changed. Accordingly, the image condition detector ICD may transmit to the integral time calculator ATC information Inf_exp about the changed integral time Tᵢₙₜ.

The integral time calculator ATC receives the information Inf_exp, calculates the adjusted integral time T_{int,adj} by multiplying the integral time Tᵢₙₜ of the image A_{j,k} by the ratio of the maximum image intensity I_{M} and the reference intensity I_{ref} as represented in Equation 14, and applies the adjusted integral time T_{int,adj} to the pixel array PA (operation S945).

The pixel array PA captures a subsequent image(s) by applying the adjusted integral time T_{int,adj} (operation S960). Otherwise, if Inequation 15 is false (“NO” in operation S944, the pixel array PA captures the subsequent image without adjusting the integral time Tᵢₙₜ (i.e., while maintaining the integral time Tᵢₙₜ) (operation S970).

Operation S980 of the depth information calculator DC is substantially the same as operation S880 in the image sensing method 800 illustrated in FIG. 8.

FIG. 10 illustrates a flowchart of an image sensing method 1000, according to another exemplary embodiment.

Referring to FIG. 10, operations S1020, S1041, S1042, and S1043 of the image sensing method 1000 are substantially the same as operations S820, S841, S842, and S843, respectively, of the image sensing method 800 illustrated in FIG. 8 and operations S920, S941, S942, and S943, respectively, of the image sensing method 900 illustrated in FIG. 9. However, instead of calculating the ratio R between the maximum image intensity I_{M} and the reference intensity I_{ref}, the integral time adjusting unit TAU according to the image sensing method 1000 may calculate a smoothed maximum image intensity I_{MA} by smooth-filtering the maximum image intensity I_{M} as represented in Equation 18 (operation S1043′). The integral time adjusting unit TAU may calculate a ratio R′ between the smoothed maximum image intensity I_{MA} and the reference intensity I_{ref} (operation S1043″), and may compare the ratio R′ to the reference value T_{R} (operation S1044), thereby detecting whether the integral time Tᵢₙₜ is changed.

$$[ Equation 18 ]$$

$${I}_{MA} ( j ) = \{ \begin{matrix}{I}_{M} ( j ) , & when j = 0 or {T}_{int} has changed \\ β \cdot {I}_{M} ( j ) + ( 1 - β ) \cdot {I}_{MA} ( j - 1 ) , & otherwise\end{matrix} \qquad$$

In Equation 18, a difference between a current maximum image intensity I_{M(j)} regarding images A_{j,0}, A_{j,1}, A_{j,2} and A_{j,3} and a recent maximum image intensity I_{M(j-1)} regarding images A_{j-1,0}, A_{j-1,1}, A_{j-1,2} and A_{j-1,3} may be reduced by oppositely multiplying a smoothing coefficient β to the current maximum image intensity I_{M(j)} and the recent maximum image intensity I_{M(j-1)}. The smoothing coefficient β has a value greater than 0 and equal to or less than 1.

Images captured initially, or images newly captured by using a new integral time, do not have the recent maximum image intensity I_{M(j-1)} by which the current maximum image intensity I_{M(j)} is to be smoothed, accordingly the smoothed maximum image intensity I_{MA} may be set equal to the maximum image intensity I_{M}.

If the smoothing coefficient β in Equation 18 is set as a large value, a time for capturing an image and then capturing a subsequent image may be reduced. If the smoothing coefficient β is set as a small value, an operation of sequentially capturing images may be performed stably.

R′(j)≧T_{R} [Inequation 19]

The ratio R′ between the smoothed maximum image intensity I_{MA} and the reference intensity I_{ref} in Inequation 19 may be calculated by using Equation 20.

$${R}^{′} ( j ) = max ( \frac{{I}_{MA} ( j )}{{I}_{ref}} , \frac{{I}_{ref}}{{I}_{MA} ( j )} ) \qquad [ Equation 20 ]$$

If Inequation 19 is true (“YES” in operation S1044), the image condition detector ICD determines that the image A_{j,k} is excessively or insufficiently exposed, i.e., that the integral time Tᵢₙₜ has changed. Accordingly, the image condition detector ICD may transmit to the integral time calculator ATC information Inf_exp about the changed integral time Tᵢₙₜ.

The integral time calculator ATC receives the information Inf_exp, calculates the adjusted integral time T_{inj,adj} by multiplying the integral time Tᵢₙₜ of the image A_{j,k} by the ratio R′ between the smoothed maximum image intensity I_{MA} and the reference intensity I_{ref} as represented in Equation 21, and applies the adjusted integral time T_{int,adj} to the pixel array PA (operation S1045).

T_{int,adj}(j,k)=Tᵢₙₜ(j,k)*(I_{ref}/I_{MA}(j)) [Equation 21]

The pixel array PA captures a subsequent image(s) by applying the adjusted integral time T_{int,adj} (operation S1060). Otherwise, if Inequation 19 is false (“NO” in operation S1044), the pixel array PA captures the subsequent image without adjusting the integral time Tᵢₙₜ (i.e., while maintaining the integral time Tᵢₙₜ) (operation S1070).

Operation S1080 of the depth information calculator DC is substantially the same as operation S880 in the image sensing method 800 illustrated in FIG. 8.

As described above, depth information may be accurately calculated without stopping the calculation of the depth information by automatically detecting whether an integral time is changed and, if the integral time is changed, adjusting the changed integral time.

Referring back to FIG. 1, the color information calculator CC of the image sensor ISEN calculates and outputs the color information C_{INF} by using the pixel output signals POUT_{c} which are output from the color pixels PX_{c} or color and depth information simultaneously detectable pixels of the pixel array PA, and are converted from analog to digital. A method of calculating the color information C_{INF} is not described in detail here.

The image sensor ISEN senses both of the color information C_{INF} and the depth information D_{INF} in FIG. 1. However, embodiments of the image sensor ISEN are not limited thereto, e.g., and the image sensor ISEN may sense only the depth information D_{INF}. The image sensor ISEN may be, e.g., a 1-tap image sensor for outputting the pixel output signals POUT_{d} (=A0˜A3) one by one or may be a 2-tap image signal for outputting the pixel output signals POUT_{d} (=A0˜A3) two by two (A0 and A2, and A1 and A3), from the depth pixels PX_{d} or the color and depth information simultaneously detectable pixels. However, embodiments of the image sensor ISEN are not limited thereto, e.g., the image sensor ISEN may simultaneously output a variety of numbers of the pixel output signals POUT_{d}.

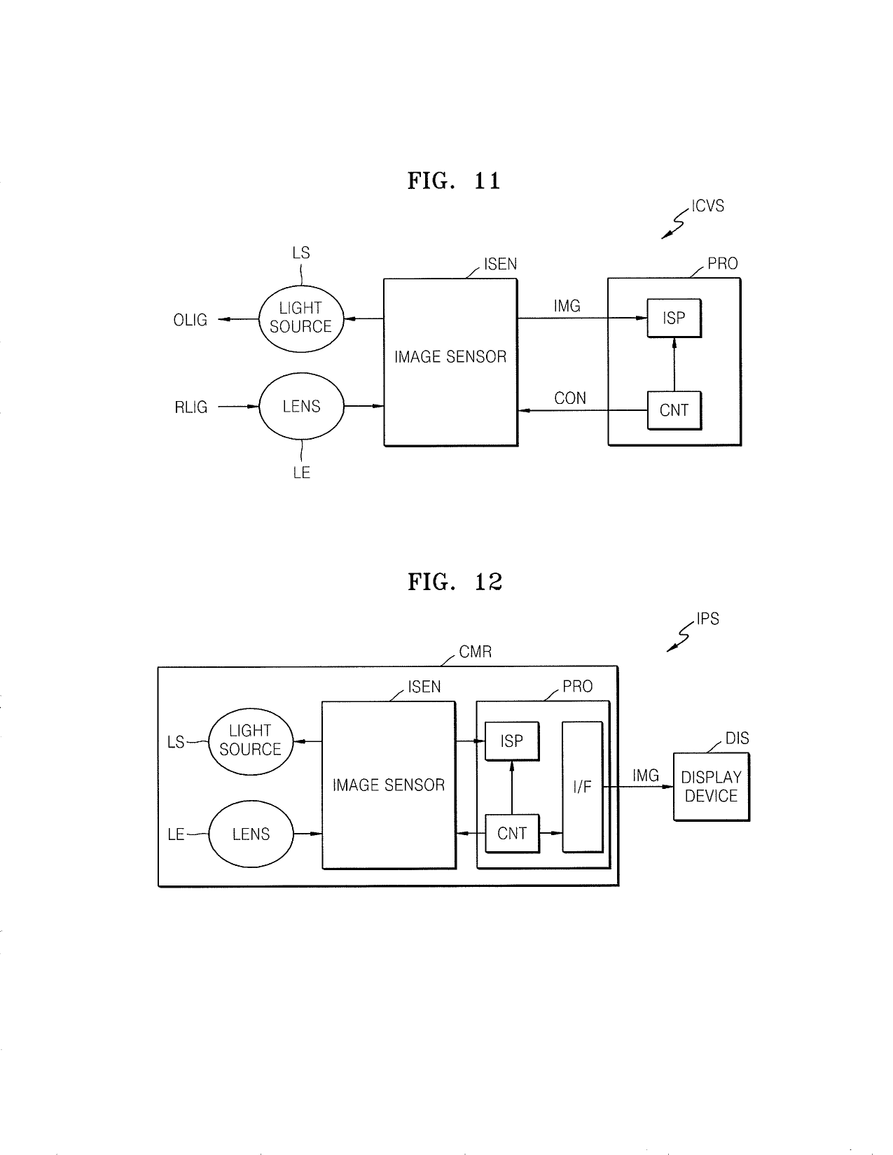

FIG. 11 illustrates a block diagram of an image capturing apparatus CMR, according to an exemplary embodiment.

Referring to FIGS. 1 and 11, the image capturing apparatus CMR may include the image sensor ISEN for sensing image information IMG regarding the object OBJ by receiving via the lens LE the reflected light RUG that is formed when the output light OLIG emitted from the light source LS is reflected on the object OBJ. The image capturing apparatus CMR may further include, e.g., a processor PRO including a controller CNT for controlling the image sensor ISEN by using a control signal CON, and a signal processing circuit ISP for signal-processing the image information IMG sensed by the image sensor ISEN. The control signal CON transmitted from the processor PRO to the image sensor ISEN may include, e.g., a first control signal and a second control signal.

FIG. 12 illustrates a block diagram of an image capture and visualizaion system ICVS, according to an exemplary embodiment.

Referring to FIG. 12, the image capture and visualizaion system ICVS may include the image capturing apparatus CMR illustrated in FIG. 11, and a display device DIS for displaying an image received from the image capturing apparatus CMR. For this, the processor PRO may further include an interface I/F for transmitting to the display device DIS the image information IMG received from the image sensor ISEN.

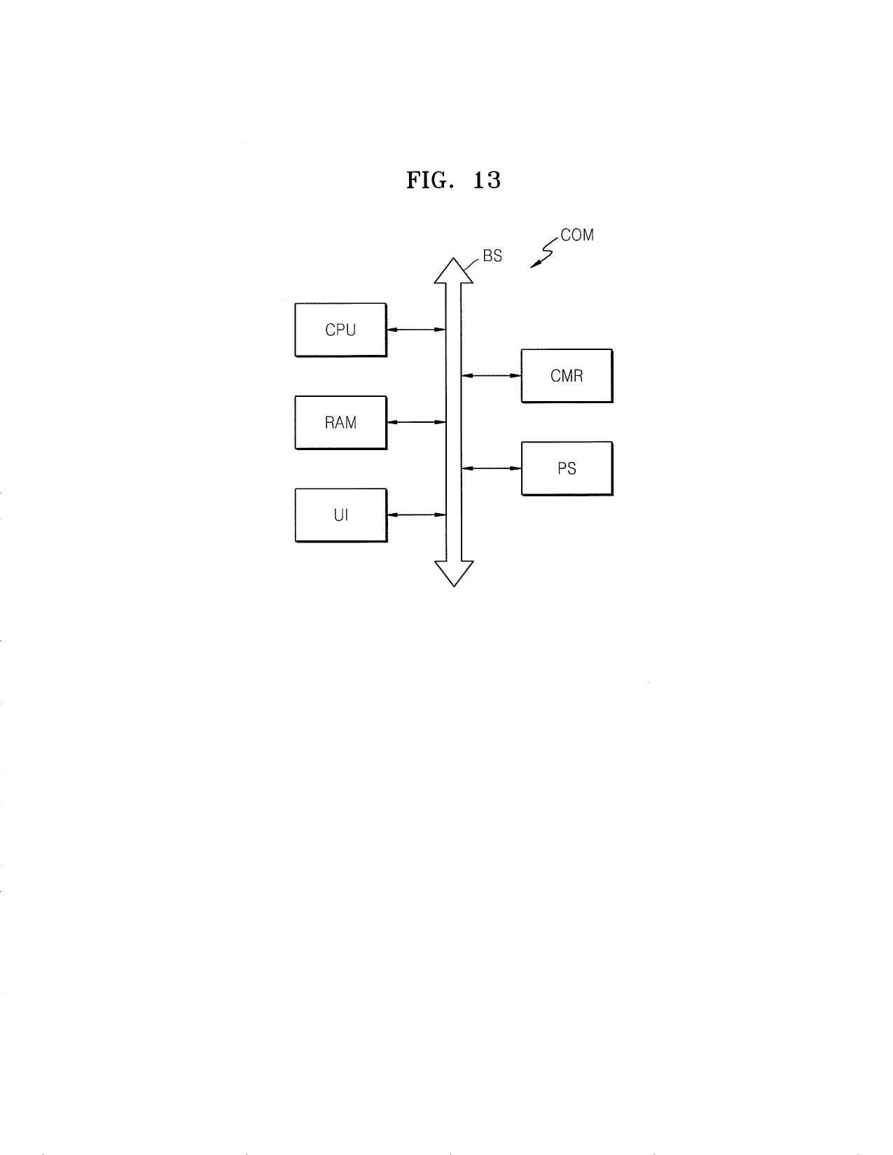

FIG. 13 illustrates a block diagram of a computing system COM, according to an exemplary embodiment.

Referring to FIG. 13, the computing system COM may include a central processing unit (CPU), a user interface (UI), and the image capturing apparatus CMR which are electrically connected to a bus BS. As described above in relation to FIG. 11, the image capturing apparatus CMR may include the image sensor ISEN and the processor PRO.

The computing system COM may further include a power supply PS. The computing system COM may also include a storing device RAM for storing the image information IMG transmitted from the image capturing apparatus CMR.

If the computing system COM is, e.g., a mobile apparatus, the computing system COM may additionally include a battery for applying an operational voltage to the computing system COM, and a modem such as a baseband chipset. Also, it is well known to one of ordinary skill in the art that the computing system COM may further include an application chipset, a mobile dynamic random access memory (DRAM), and the like, and thus detailed descriptions thereof are not provided here.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor that receives reflected light from an object having an output light incident thereon, the image sensor comprising:
a pixel array including pixels that sample a plurality of modulation signals having different phases from the reflected light and that output pixel output signals corresponding to the plurality of modulation signals, the output pixel output signals being used to generate first images; and
an integral time adjusting unit that detects a change in an integral time applied to generate the first images such that the integral time adjusting unit compares intensities of the first images to a reference intensity and determines an adjusted integral time when the change in the integral time is detected,
wherein, when the change in the integral time is detected, the pixel array generates second images that are subsequent to the first images by applying the adjusted integral time determined by the integral time adjusting unit based on the first images.

2. The image sensor as claimed in claim 1, wherein the integral time adjusting unit includes:
an image condition detector that generates a control signal indicating whether the first images are excessively or insufficiently exposed, by comparing the intensities of the first images to the reference intensity, and
an integral time calculator that calculates the adjusted integral time in response to the control signal.

3. The image sensor as claimed in claim 2, wherein the image condition detector compares a maximum image intensity among the intensities of the first images to the reference intensity.

4. The image sensor as claimed in claim 3, wherein the integral time calculator calculates the adjusted integral time by multiplying a non-adjusted integral time by a ratio of the maximum image intensity and the reference intensity.

5. The image sensor as claimed in claim 2, wherein the image condition detector compares a ratio of a maximum image intensity among the intensities of the first images and the reference intensity to a reference value.

6. The image sensor as claimed in claim 5, wherein the ratio of the maximum image intensity and the reference intensity is equal to or greater than 1.

7. The image sensor as claimed in claim 6, wherein the reference value is equal to or greater than 0 and is set as a value equal to or less than an inverse of a factor, the reference intensity being equal to the factor multiplied by a maximum pixel output signal from among the pixel output signals in a normal state of the image sensor.

8. The image sensor as claimed in claim 5, wherein the integral time calculator calculates the adjusted integral time by multiplying a non-adjusted integral time by the ratio of the maximum image intensity and the reference intensity.

9. The image sensor as claimed in claim 2, wherein the image condition detector compares a ratio of the reference intensity and a smoothed maximum image intensity with a reference value, the smoothed maximum image intensity being calculated by smooth-filtering a maximum image intensity among the intensities of the first images.

10. The image sensor as claimed in claim 9, wherein the integral time calculator calculates the adjusted integral time by multiplying a non-adjusted integral time by the ratio of the smoothed maximum image intensity and the reference intensity.

11. The image sensor as claimed in claim 1, further comprising a depth information calculator that calculates depth information regarding the object by estimating a delay between the output light and the reflected light from the first images that have different phases and that have a same integral time as the second images.

12. The image sensor as claimed in claim 1, wherein each of the modulation signals is phase-modulated from the output light by one of about 0°, 90°, 180°, and 270°.

13. The image sensor as claimed in claim 1, wherein the pixel array includes:
color pixels that receive wavelengths of the reflected light for detecting color information regarding the object and that generate pixel output signals of the color pixels corresponding to the received wavelengths, and
depth pixels that receive wavelengths of the reflected light for detecting depth information regarding the object and that generate pixel output signals of the depth pixels corresponding to the received wavelengths,
wherein the image sensor further comprises a color information calculator that receives the pixel output signals of the color pixels and calculates the color information.

14. The image sensor as claimed in claim 1, wherein the image sensor is a time of flight image sensor.

15. An image sensing method using an image sensor that receives reflected light from an object having an output light incident thereon, the image sensing method comprising:
sampling, from the reflected light, a plurality of modulation signals having different phases, and sequentially generating first images by simultaneously outputting pixel output signals corresponding to the plurality of modulation signals; and
detecting a change in an integral time applied to generate the first images by comparing intensities of the first images to a reference intensity and determining an adjusted integral time when the change in the integral time is detected,
when the change in the integral time is detected, forming second images that are subsequent to the first images by applying the adjusted integral time to the second images.

16. An image sensor for sensing an object, the image sensor comprising:
a light source driver that emits output light toward the object;
a pixel array including a plurality of pixels that convert light reflected from the object into an electric charge to generate first images;
an integral time adjusting unit connected to the pixel array, the integral time adjusting unit detects a change in an integral time applied to generate the first images such that the integral time adjusting unit compares intensities of the first images to a reference intensity and determines an adjusted integral time when the change in the integral time is detected,
wherein, when the change in the integral time is detected, the pixel array generates second images that are subsequent to the first images by applying the adjusted integral time determined by the integral time adjusting unit based on the first images.

17. The image sensor as claimed in claim 16, wherein:
when the change in the integral time is detected, the integral time adjusting unit calculates a maximum image intensity among the intensities of the first images,
when the maximum image intensity is less than the reference intensity, the pixel array generates the second images by applying a non-adjusted integral time, and
when the maximum image intensity is greater than or equal to the reference intensity, the pixel array generates the second images by applying the adjusted integral time.

18. The image sensor as claimed in claim 16, wherein:
when the change in the integral time is detected, the integral time adjusting unit calculates a maximum image intensity among the intensities of the first images and calculates a ratio of the maximum image intensity and the reference intensity,
when the ratio is less than a reference value, the pixel array generates the second images by applying a non-adjusted integral time, and
when the ratio is greater than or equal to the reference value, the pixel array generates the second images by applying the adjusted integral time.

19. The image sensor as claimed in claim 16, wherein:
when the change in the integral time is detected, the integral time adjusting unit calculates a maximum image intensity among the intensities of the first images, calculates a smoothed maximum image intensity, and calculates a ratio of the smoothed maximum image intensity and the reference intensity,
when the ratio is less than a reference value, the pixel array generates the second images by applying a non-adjusted integral time, and
when the ratio is greater than or equal to the reference value, the pixel array generates the second images by applying the adjusted integral time.

20. The image sensor as claimed in claim 16, wherein the integral time adjusting unit includes:
an image condition detector that compares the intensities of the first images to the reference intensity and outputs a corresponding signal, and
an integral time calculator that receives the corresponding signal from the image condition detector and determines the adjusted integral time.
